(19) United States
(12) Patent Application Publication
(10) Pub. No.: US 2019/0166693 A1
(43) Pub. Date: May 30, 2019

(54) HEARING DEVICE AND METHOD OF MANUFACTURING A HEARING DEVICE

(71) Applicant: SIVANTOS PTE. LTD., SINGAPORE (SG)

(72) Inventors: VOLKER GEBHARDT, NEUNKIRCHEN AM BRAND (DE); HOLGER KRAL, FUERTH (DE); CHRISTIAN SCHMITT, GROSSENSEEBACH (DE)

(21) Appl. No.: 16/202,621

(22) Filed: Nov. 28, 2018

(30) Foreign Application Priority Data
Nov. 28, 2017 (DE) 102017221332.9

(51) Int. Cl. H05K 1/14; H05K 1/18; H05K 3/36; H04R 25/00

(52) U.S. Cl. CPC H05K 1/144; H05K 1/181; H05K 1/182; H05K 3/368; H04R 2225/51; H05K 2201/10098; H05K 2201/042; H05K 2201/0715; H04R 25/554

(57) ABSTRACT

A hearing device has a printed circuit board with two carrier segments, which respectively each have a carrier layer to which a conductor structure adheres, and also with a connecting segment that connects the two carrier segments to each other. The connecting segment is configured so as to be bendable and rotatable.

### CROSS-REFERENCE TO RELATED APPLICATION

This application claims the priority, under 35 U.S.C. § 119, of German application DE 10 2017 221 332.9, filed Nov. 28, 2017; the prior application is herewith incorporated by reference in its entirety.

### BACKGROUND OF THE INVENTION

### Field of the Invention

The invention relates to a hearing device having a printed circuit board having two carrier segments that each respectively have a carrier layer to which a conductor structure adheres, and a connecting segment that connects the two carrier segments together. Such a hearing device may be found for example in German patent DE 10 2008 008 897 B3.

“Hearing devices” typically refer to classical hearing aids that are used to care for the hearing impaired. In a broader sense, however, this term also refers to devices that are configured to support normally hearing people. Such hearing devices are also referred to as “Personal Sound Amplification Products” or “Personal Sound Amplification Devices” (“PSAD”). Rather than being intended to compensate for hearing loss, these devices are used in a targeted way to support and improve normal human hearing ability in specific listening situations, such as assisting hunters in hunting or supporting wildlife observation to be able to better perceive animal cries and other animal-generated sounds; for sports reporters, to allow for improved speech and/or speech comprehension in complex soundscapes; for musicians, to reduce noise exposure, etc.

Regardless of the intended application, typically the essential components of hearing devices are an input transducer; a signal processing device, which typically contain an amplifier; and an output transducer. The input transducer is usually configured as an acousto-electric transducer, that is, for example, as a microphone, and/or an electromagnetic receiver, for example an induction coil. For the output transducer, an electroacoustic transducer is usually used, such as a miniature speaker (also referred to as a “receiver”), or an electromechanical transducer, for example, a bone conduction receiver, and the signal processing device is usually realized by an electronic circuit realized on a printed circuit board.

### SUMMARY OF THE INVENTION

On this basis, the objective of the invention is to provide an advantageously configured hearing device and an advantageous method of manufacturing a hearing device.

This objective is achieved according to the invention by a hearing device having the features of the independent hearing device claim and by a method having the features of main method claim. Preferred developments are contained in the dependent claims. The advantages and preferred configurations mentioned with regard to the hearing device may analogously be transferred to the method and vice versa.

A corresponding hearing device, in this case, is preferably designed as a classical hearing aid and, for example, an ITE hearing device (ITE: In-The-Ear), an ITC hearing device (ITC: In-The-Canal), a CIC hearing device (CIC: Complete-In-Canal) or an IIC hearing device (IIC: Invisible-In-Canal).

The hearing device in this case has a printed circuit board having two carrier segments and a connecting segment, wherein the connecting segment connects the two carrier segments together, and in particular connects them both mechanically and electrically. With the aid of this printed circuit board, a signal processing device is expediently realized which comprises or forms an amplifier that is for example characteristic of a corresponding hearing device. In this case, each carrier segment has a carrier layer, to which a conductor structure adheres and to which a number of electrical and/or electronic components are typically attached. These electrical and/or electronic components are then typically electrically connected to one another via the conductor structures on the carrier layers of the carrier segments, and in some cases also via the connecting segments for forming an electronic circuit, and accordingly the connecting segment preferably has a number of electrical lines or a conductor structure, so that the connecting segment connects the carrier segments to one another not only mechanically but also in particular electrically. The connecting segment is therefore part of the printed circuit board in all cases.

In addition, the connecting segment is configured to be bendable and rotatable, i.e. in particular twistable, so that the printed circuit board is configured to be at least partially or segmentally, and preferably only partially or segmentally, flexible, or is configured as a kind of foldable printed circuit board. The carrier segments, in contrast, are preferably configured to be relatively rigid and thus not substantially bendable or twistable.

The manufacture of such a printed circuit board takes place, for example, by suitably combining or assembling one or more rigid layers, for example from FR4, and one or more flexible layers, for example from polyimide. The rigid layer or rigid layers are then preferably removed in the course of the further printed circuit board manufacture by a depth milling, in the intended region of the connecting segment or in the intended regions of the connecting segments. This results in a printed circuit board with regions that form rigid carrier segments and are connected by regions that form flexible connecting elements.

As a result, the carrier segments may be arranged and oriented freely relative to each other, at least to a limited extent. This in turn makes it possible to adapt, in particular to individually adapt, the shape of the printed circuit board to its carrier segments and the connecting segment, and thus also to adapt the shape of the printed circuit board to a given installation space or to an installation space furnished in a housing of the hearing device.

In particular, as a result of the adaptability of the shape of the printed circuit board, an advantageous method of manufacturing hearing devices is made possible, and preferably also implemented. In this method, hearing devices are preferably manufactured in such a way that an above-described printed circuit board is prefabricated, and subsequently or later the connecting segment is bent and/or rotated or twisted, prior to inserting the printed circuit board into the housing of the hearing device, in order to move the printed circuit board into an intended installation state and realize an intended or predetermined shape of the printed circuit board, and that finally the printed circuit board formed in this way is inserted into the housing. The bending and/or rotation of the connecting segment is preferably carried out immediately before inserting the printed circuit board into the housing, and preferably not in the course of prefabricating the printed circuit board. Alternatively, the bending and/or rotation takes place almost at the same time as inserting the printed circuit board into the housing, for example by first introducing one of the carrier segments into the inner space of the housing and then bringing the other carrier segment in behind it, as it were, by bending and/or rotating the connecting segment inside the inner space of the housing.

In an advantageous development, such a method of manufacturing hearing devices is used to manufacture custom-made or individually adapted hearing devices. In these custom-made or individually adapted hearing devices, the housings are preferably configured individually, and expediently have an outer shape that is respectively adapted to an ear and in particular to an ear canal of a user or wearer. In this case, a corresponding housing, for example, a housing shell and a faceplate, has or consists of precisely these two parts. The faceplate is preferably configured as a standardized faceplate and thus is configured similarly in all hearing devices of a hearing device batch, or a series of individually adapted hearing devices. In this case, the individually configured, individually adapted or custom-made housings differ with regard to the configuration or shape of the housing shells, which are expediently individually adapted to an ear, and in particular an ear canal, of a user or wearer.

As a result of this individual adaptation in particular of the outer shape of a corresponding custom-made housing, typically the inner space of a corresponding housing, i.e. the usable space in which the circuit board will be arranged, is configured individually, and for this reason, the printed circuit board is preferably inserted individually-formed into the installation space, where the connecting segment of the printed circuit board is individually bent and/or individually rotated or twisted. However, the printed circuit board itself is preferably prefabricated as a standardized structural unit and is preferably individualized, solely for the purpose of adapting it to the individual inner space or installation space of the associated housing of the respective hearing device, by individually bending and/or individually rotating the connecting segment.

In this way, for example, a hearing device is manufactured, which is configured as a custom-made hearing device and has a custom-made housing with an individually configured inner space and printed circuit board, the printed circuit board being configured as a standardized printed circuit board. In other words, the printed circuit boards of two completed, custom-made hearing devices preferably differ solely with regard to the bending and/or rotation of the connecting segment. However, because in that case the respective connecting segment was individually bent and/or individually twisted before inserting the respective printed circuit board into the associated custom-made housing, the respective printed circuit board is individually adapted to the individually designed inner space. As a result, in this case the respective hearing device itself is also individualized or custom-made.

If such a hearing device additionally has a housing with a faceplate and in particular with a standardized faceplate, preferably one of the two carrier segments of the printed circuit board is fastened to this faceplate.

As a result of the above-described individualization, a hearing device batch or series that has been manufactured has a plurality of similar hearing devices, and each of these hearing devices is configured as a custom-made hearing device having a custom-made housing with an individually configured inner space, and as a result, the housings of these hearing devices differ from one another with regard to design. In addition, the respectively associated printed circuit board of each of these hearing devices is preferably prefabricated as a standardized printed circuit board, the respectively associated connecting segment having been individually bent and/or individually twisted before inserting the printed circuit board into the associated custom-made housing, so that the respectively associated printed circuit board is individually adapted to the individually designed inner space.

In other words, when fully manufactured, the custom-made hearing devices of the hearing device batch or series preferably differ only with regard to the configuration of the housing and the bending and/or rotation of the connecting segment. In contrast, the functions realized and/or enabled in the hearing devices are preferably the same for all of the custom-made hearing devices in the hearing device batch or series.

Corresponding to an alternative embodiment, the custom-made hearing devices of the hearing device batch or series, in their finished state, additionally differ with regard to the position and/or orientation of the printed circuit board within the housing, and in particular the position and/or orientation of the faceplate, if present.

Also expedient is an embodiment in which individual positions and/or individual orientations are also furnished for further electrical or electronic components of the printed circuit board within the housing for the custom-made hearing devices of the hearing device batch or hearing device series, and in particular with reference to the position and/or orientation of the faceplate, if available. In this way, spatial arrangements are realized that are virtually distinct and thus individual; while in contrast, the logical or functional relationship among these components is the same in all hearing devices of the hearing device batch or series, so that the same functionality is realized and/or enabled in all custom-made hearing devices of the hearing device batch or series.

Depending on the use case, further in the course of the manufacturing process, i.e. in the course of manufacturing a hearing device, a coating of a solidifying mass such as a shielding material is applied. The coating is preferably applied after the printed circuit board has been shaped for insertion into the housing, and thus in particular after the connecting segment has been bent and/or twisted. In some cases, the solidifying mass then serves, or in addition to other purposes also serves, to fix the shape of the printed circuit board, i.e. in particular to fix the bending position and/or rotational position of the connecting segment.

The concept presented herein may be easily transferred to printed circuit boards with more than two carrier segments and/or more than one connecting segment.

In addition, the printed circuit board, as mentioned above, is preferably prefabricated and is also preferably designed as a standardized assembly. Regardless, if the two carrier segments are in the extended, unfolded or opened state, that is to say if the connecting segment is unbent and untwisted, they are typically arranged side by side along a connecting axis and are connected to one another via the connecting element located between them. In this state, the corresponding carrier elements may then be rotated in mutually opposite directions about the connecting axis located between them, via the connecting element, thus imposing a kind of torsion on the connecting element. Alternatively or in addition, the connecting element may be bent, and in particular may be bent about an axis transverse to the connecting axis, and as a result, the printed circuit board is virtually foldable.

In many cases, in the extended state, the two carrier segments have a greater extension, viewed transversely to the connecting axis, than the connecting segment arranged between the two carrier segments. In this case, the extension of the connecting segment transverse to the connecting axis is preferably less than 70%, more preferably less than 50%, and in particular less than 30% of the extension of one of the carrier segments, or both carrier segments, transverse to the connecting axis.

In addition, the connecting segment is preferably configured in such a way that the two carrier segments may be rotated in mutually opposite directions, starting from the aforementioned extended state, by twisting the connecting segment about the connecting axis, preferably by an angle >30°, more preferably >60° and in particular >90° or even >180°. The maximum possible twisting angle in this case typically depends on the width and length of the connecting segment. This in turn usually depends on the intended installation position. In general, however, the highest possible twistability is desirable.

In addition, a configuration of the connecting segment is advantageous in which the connecting segment is configured in the manner of a ribbon cable or is formed by a ribbon cable.

In order to make it possible for the connecting segment to be twistable and bendable in particular in different directions, it is also advantageous if the connecting segment is configured so as to be S-shaped or meandering rather than straight. Along an S-shaped or meandering connecting segment, there would also automatically be sections with different preferred bending directions.

Finally, the carrier segments typically carry a number of electrical and/or electronic components, which typically form a signal processing device as set forth above, in combination with the printed circuit board, i.e. in particular also in combination with the connecting segment. In this case, at least one electronic component is preferably configured as an integrated circuit (IC), by means of which processing of electrical signals is made possible.

In addition, it is expedient if at least one of the carrier segments carries an antenna for radio waves. In some embodiments, such an antenna is configured in such a way that it protrudes from the corresponding carrier segment. Alternatively, such an antenna is formed by conductor structures on one of the carrier segments and/or on both carrier segments.

Other features which are considered as characteristic for the invention are set forth in the appended claims.

Although the invention is illustrated and described herein as embodied in a hearing device and a method of manufacturing a hearing device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, top plan view of a first embodiment of a printed circuit board in an extended state according to the invention;

FIG. 2 is a sectional view of a first embodiment of a hearing device with a first custom-made housing and the first embodiment of the printed circuit board in a first installation state;

FIG. 3 is a sectional view of a second embodiment of the hearing device with a second custom-made housing and the first embodiment of the printed circuit board in a second installation state;

FIG. 4 is a sectional view of a third embodiment of the hearing device with a third custom-made housing and the first embodiment of the printed circuit board, in a third installation state;

FIG. 5 is a side view of a second embodiment of the printed circuit board in an installation state;

FIG. 6 is a top plan view of a third embodiment of a printed circuit board in an extended state;

FIG. 7 is a sectional view of a fourth embodiment of the hearing device with a fourth custom-made housing and a fourth embodiment of a printed circuit board in a fourth installation state; and

FIG. 8 is a sectional view of a fifth embodiment of the hearing device with a fifth custom-made housing and the fourth embodiment of the printed circuit board, in a fifth installation state.

### DETAILED DESCRIPTION OF THE INVENTION

Corresponding parts are respectively assigned the same reference numerals in all drawings.

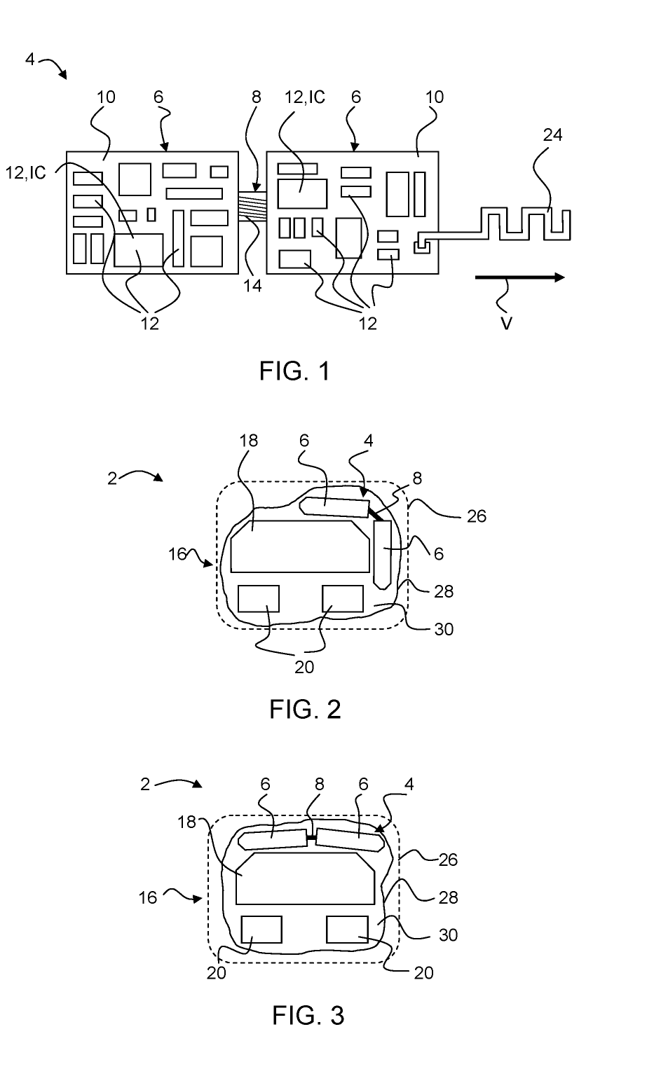

Referring now to the figures of the drawings in detail and first, particularly to FIG. 1 thereof, there is shown a hearing device 2, which is described below by way of example, is preferably configured as a classical hearing aid and configured, for example, as an in-the-canal (ITC) hearing device.

In this case, the hearing device 2 has a printed circuit board 4 with two carrier segments 6 and with a connecting segment 8, wherein the connecting segment 8 connects the two carrier segments 6 with each other. The printed circuit board 4 is typically prefabricated and is shown in FIG. 1 in a first embodiment in an extended state. In this extended state, the two carrier segments 6 are arranged side by side along a connecting axis V, with the connecting segment 8 positioned between the two carrier segments 6. In this case, each carrier segment 6 has a carrier layer 10, to which a conductor structure (not shown) adheres and to which are typically fastened a number of electrical and/or electronic components 12 that are connected to one another via the conductor structure.

By means of the printed circuit board 4 and the electrical and/or electronic components 12, an electronic circuit is then realized, which serves as a signal processing device and typically contains an amplifier that is characteristic of a corresponding hearing device 2. In this case, conductors 14, or conductor structures that are components of the connecting segment 8 and electrically connect the two carrier segments 6 with each other, are also a part of this electronic circuit. To this end, the connecting segment 8 is configured for example as a ribbon cable.

In addition, the connecting segment 8 is configured to be bendable and rotatable, i.e. in particular twistable, so that the printed circuit board 4 is configured to be at least partially or segmentally, and preferably only partially or segmentally, flexible, and the shape of the printed circuit board 4 may be adapted accordingly. The carrier segments 6, in contrast, are relatively rigid and accordingly are not flexible. In the extended state, the connecting segment 8 still remains unbent and untwisted. Starting from this state, the corresponding carrier elements 6 may then be rotated in mutually opposite directions about the connecting axis V via the connecting element 8, imposing a kind of torsion on the connecting element 8. Alternatively or in addition, the connecting element 8 may be bent, in particular about an axis transverse to the connecting axis V, and as a result, the printed circuit board 4 is virtually foldable. Due to the adaptability of the shape of the printed circuit board 4, an advantageous method of manufacturing hearing devices 2 is thus made possible, and preferably also implemented.

In this method, hearing devices 2 are preferably manufactured in such a way that first an above-described printed circuit board 4 is prefabricated, and later the connecting segment 8 is bent and/or twisted, prior to inserting the printed circuit board 4 into a housing 16 of the hearing device 2, in order to move the printed circuit board 4 into an intended installation state and realize an intended or predetermined shape of the printed circuit board 4, and that finally the printed circuit board 4 formed in this way is inserted into the housing 16. The bending and/or rotation of the connecting segment 8 preferably takes place immediately before inserting the printed circuit board 4 into the housing 16 and preferably not in the course of prefabricating the printed circuit board 4.

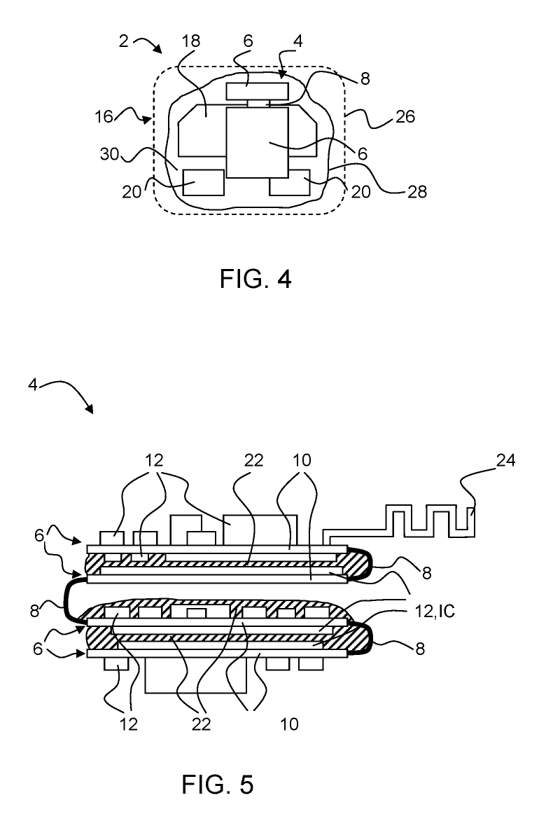

In an advantageous development, such a method is used to manufacture custom-made or individually-adapted hearing devices 2. In this case, the housings 16 of the hearing devices 2 are preferably configured individually and have an individually-configured external shape and an individually-configured installation space or inner space 30. Three examples of such individually adapted hearing devices 2 are indicated in FIGS. 2 to 4.

The other parts or assemblies, such as a battery and two microphones 20, in contrast, are preferably configured as standardized components or assemblies. The printed circuit board 4 is also preferably prefabricated at least as a standardized assembly and is only individualized in that the printed circuit board 4 is individually shaped and as a result is adapted to the individually-configured installation space or inner space 30, while the connecting segment 8 of the printed circuit board 4 is individually bent and/or individually twisted. In consequence, three different installation states of the printed circuit board 4 are reproduced in FIG. 2 to FIG. 4, in which each printed circuit board 4 respectively has an individual shape. For simplicity of illustration, only different bending positions are shown and an illustration of different rotational positions of the connecting segment 8 has been dispensed with.

The custom-made hearing devices 2, according to FIGS. 2 to 4, thus preferably have only individualized housings 16 as well as individually bent and/or individually twisted connecting segments 8, and are otherwise the same. Together these devices form a hearing device batch or series, made up of hearing devices 2 that are similar but custom-made, and the same functions are realized and/or enabled in all of them. They therefore do not differ with regard to the signal processing carried out in the signal processing device.

The individualized housings 16 in turn, according to one embodiment, each respectively have a custom-made housing shell 28 and a standardized faceplate 26. FIGS. 2 to 4 show sectional views in which the sectional plane, corresponding to the plane of the drawing, is parallel to the faceplate 26. The faceplate 26 is then outside the plane of the drawing and is indicated by a dashed outline.

Two additional examples of custom-made hearing devices 2 are shown in FIGS. 7 and 8. Here, the sectional plane of the sectional views is oriented perpendicular to the faceplate 26.

Depending on the use case, further in the course of the manufacturing process, i.e. in the course of manufacturing a hearing device 2, a solidifying mass such as for example a shielding material 22 is coated onto the printed circuit board 4, in particular to shield individual electrical or electronic components, and sometimes to shield them from each other. The coating is preferably carried out after the printed circuit board 4 has been formed for insertion into the housing 16, and thus in particular after the connecting segment 8 has been bent and/or twisted. A corresponding exemplary embodiment is reproduced in FIG. 5.

In this embodiment, the printed circuit board 4 has four carrier segments 6 and three connecting segments 8. In addition, the shielding material 22 preferably also serves to at least partially fix the shape of the printed circuit board 4; in other words, in the exemplary embodiment, it serves to fix the bending position and/or rotational position of the connecting segments 8 on the right-hand side in FIG. 5.

In the exemplary embodiment of FIG. 5, the carrier segments 6 again carry a number of electrical and/or electronic components 12, which, as already stated above, typically form a signal processing device in combination with the printed circuit board 4, and thus in particular also in combination with the connecting segments 8. Preferably in this case, at least one electronic component 12 is designed as an integrated circuit (IC), which makes the processing of electric signals possible.

In addition, one of the carrier segments 6 carries an antenna 24 for radio waves. This antenna is configured in such a way that it protrudes from the corresponding carrier segment. Alternatively, such an antenna 24 is formed by conductor structures on one of the carrier segments 6 and/or on carrier segments 6.

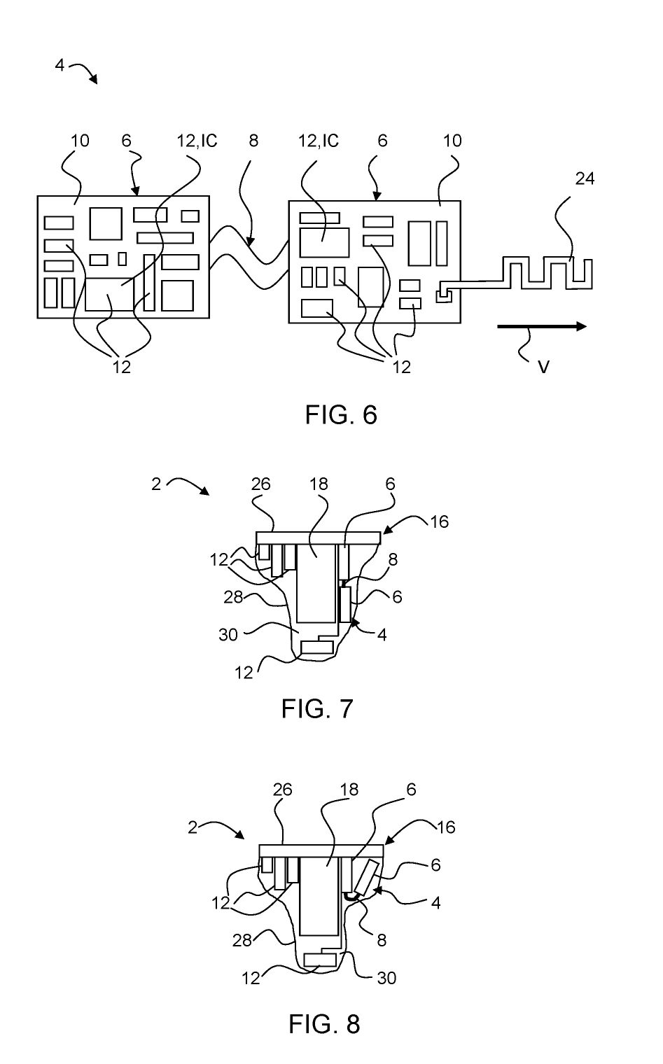

Finally, FIG. 6 depicts a modified embodiment of the printed circuit board 4 of FIG. 1, which is shown here in an extended state. In contrast to the embodiment of FIG. 1, in this case the connecting segment 8 is not configured as a straight connecting segment 8, but as an S-shaped connecting segment 8.

The invention is not limited to the above-described exemplary embodiment. Rather, other variants of the invention may also be derived therefrom by a person of ordinary skill in the art, without departing from the subject matter of the invention. In particular, all the individual features described in connection with the exemplary embodiment may also be combined with each other in other ways, without departing from the subject matter of the invention.

The following is a summary list of reference numerals and the corresponding structure used in the above description of the invention:
2 Hearing device
4 Printed circuit board
6 Carrier segment
8 Connecting segment
10 Carrier layer
12 Electronic component
14 Conductor
16 Housing
18 Battery
20 Microphone
22 Shielding material
24 Antenna
26 Faceplate
28 Housing shell
30 Inner space
V Connecting axis
IC Integrated circuit

1. A hearing device, comprising:
a printed circuit board having two carrier segments and a connecting segment connecting said two carrier segments to each other, each of said carrier segments having a carrier layer and a conductor structure adhering to said carrier layer, said connecting segment configured so that said connecting segment may be bent and rotated.

2. The hearing device according to claim 1, wherein when said printed circuit board is in an extended state, said two carrier segments are disposed side by side along a connecting axis, and said two carrier segments may be rotated in mutually opposite directions about the connecting axis via said connecting segment located between them.

3. The hearing device according to claim 1, wherein when said printed circuit board is in an extended state, said two carrier segments are disposed side by side along a connecting axis, and said two carrier segments, viewed transversely to the connecting axis, have a greater extension than said connecting segment that is disposed between said two carrier segments.

4. The hearing device according to claim 3, wherein the extension of said connecting segment transverse to the connecting axis is less than 60% of an extension of one of said carrier segments transverse to the connecting axis.

5. The hearing device according to claim 1, wherein said carrier segments carry electronic components.

6. The hearing device according to claim 1, further comprising an antenna for radio waves, one of said carrier segments carries said antenna which protrudes from said one carrier segment.

7. The hearing device according to claim 1, wherein said connecting segment is a ribbon cable.

8. The hearing device according to claim 1, wherein:
the hearing device is a custom-made hearing device and has a custom-made housing with an individually configured inner space in addition to said printed circuit board;
said printed circuit board is a standardized printed circuit board; and
said connecting segment is individually bent and/or individually twisted prior to inserting said printed circuit board into said custom-made housing, so that said printed circuit board is individually adapted to said individually configured inner space.

9. The hearing device according to claim 8, further comprising a faceplate and one of said two carrier segments of said printed circuit board is fastened to said faceplate.

10. The hearing device according to claim 3, wherein the extension of said connecting segment transverse to the connecting axis is less than 40% of an extension of one of said carrier segments transverse to the connecting axis.

11. A hearing device batch, comprising:
a plurality of hearing devices, each of said hearing devices having a printed circuit board with two carrier segments and a connecting segment connecting said two carrier segments to each other, each of said carrier segments having a carrier layer and a conductor structure adhering to said carrier layer, said connecting segment configured so that said connecting segment may be bent and rotated; and
each of said hearing devices configured as a custom-made hearing device having a custom made housing with an individually configured inner space, as a result of which said custom made housing of each of said hearing devices are distinct from one another with regard to a configuration;
said circuit board is configured as a standardized printed circuit board; and
said connecting segment of each of said hearing devices is individually bent and/or individually twisted prior to inserting said printed circuit board into said custom-made housing, so that said printed circuit board is individually adapted to said individually configured inner space.

12. A method for manufacturing a hearing device, which comprises the steps of:
providing a housing;
providing a printed circuit board with two carrier segments that each respectively have a carrier layer and a conductor structure adhering to the carrier layer, and also with a connecting segment that connects the two carrier segments, the printed circuit board is prefabricated and the connecting segment is bent and/or twisted before inserting the printed circuit board into the housing.

13. The method according to claim 12, which further comprises:
configuring the hearing device as a custom-made hearing device having a custom-made housing with an individually configured inner space in addition to the printed circuit board;
forming the printed circuit board as a standardized printed circuit board; and
individually bending and/or twisting the connecting segment prior to inserting the printed circuit board into the custom-made housing, so as to individually adapt the printed circuit board to the individually configured inner space.

14. The method according to claim 12, wherein after the printed circuit board has been bent and/or twisted, coating a shielding material onto at least one section of the printed circuit board which fixes a shape of the printed circuit board.
